(19) United States
(12) Patent Application Publication
(10) Pub. No.: US 2026/0304566 A1
(43) Pub. Date: Oct. 1, 2026

(54) COOKING APPARATUS USING INDUCTION HEATING

(71) Applicant: LG ELECTRONICS INC., Seoul (KR)

(72) Inventors: Donguk Jeong, Seoul (KR); Junhan Park, Seoul (KR); Sunghyun Ki, Seoul (KR); Seungbok Ok, Seoul (KR); Byungjae Choi, Seoul (KR)

(73) Assignee: LG ELECTRONICS INC., Seoul (KR)

(21) Appl. No.: 19/634,622

(22) Filed: Mar. 31, 2026

(30) Foreign Application Priority Data
Apr. 1, 2025 (KR) 10-2025-0042184

(51) Int. Cl. H05B 6/12; H05B 1/02

(52) U.S. Cl. CPC H05B 6/1209; H05B 1/0202; H05B 6/1245

(57) ABSTRACT

A cooking apparatus using induction heating of the present disclosure includes: a top plate including a heating zone on which a cooking container is placed; a working coil located below the heating zone; an inverter which has a plurality of switching elements, and supplies current to the working coil through an operation of the plurality of switching elements; a first sensor which acquires vibration data in an audible frequency band; and a controller which first determines whether contents of the cooking container are boiling based on the vibration data acquired from the first sensor, secondly determines whether the contents are boiling based on power amount data of the working coil, and determines whether the contents are boiling based on a result of the first determination and a result of the second determination.

### TECHNICAL FIELD

This disclosure relates to a cooking apparatus using induction heating, and more particularly, to a cooking apparatus using induction heating capable of improving reliability.

### BACKGROUND

A cooking apparatus, as one type of home appliance for cooking food, may refer to an apparatus installed in a kitchen space that cooks food according to the user's intentions. These cooking apparatuses can be classified into various categories depending on the type of heat source and fuel used.

Recently, among cooking apparatuses, the market for electric ranges has been steadily expanding. This is because electric ranges do not produce carbon monoxide during combustion and there is a lower risk of safety accidents such as gas leaks or fires.

Meanwhile, electric ranges can be categorized into a Hi-Light type which uses a high-resistance nichrome wire to convert electricity into heat, and an induction type which generates an electric magnetic field and applies heat through electromagnetic induction.

Induction cooking apparatuses operate to generate strong magnetic lines of force by inducing a high-frequency current through a built-in working coil. When the magnetic field generated by the working coil passes through a cooking utensil, such as a metal pot, eddy currents are generated in the cooking utensil. As eddy currents flow through the cooking utensil, heat is generated to heat the cooking utensil itself, so that the contents inside the cooking utensil are also heated.

Meanwhile, in order for food to be cooked properly according to the user's intention, the cooking utensils need to be heated to an appropriate temperature and a corresponding temperature needs to be maintained continuously.

At this time, it is not only a very cumbersome task for a user to directly measure the temperature of the cooking utensil or the contents inside the cooking utensil using a thermometer, but it may also cause safety issues.

One of the most inconvenient things when using an induction is boiling over. If a user does something else while cooking, soup may boil over to leave an area around the induction and a container dirty. Various attempts have been made to address this issue.

For example, a method that detects the boiling time point by inserting a probe-type rod equipped with a temperature sensor into a container, and a method that detects the vibration frequency of the boiling time point by attaching a vibration sensor to an induction top plate are representative examples. Prior art (Korean Patent Publication No. 10-2022-0147895) discloses a technology that detects the boiling of contents in a cooking utensil based on the amplitude of vibration data.

Probe-type temperature sensors have the disadvantage of being complex to use, degrading the hygiene of a load inside the container, and requiring frequent recharging of temperature sensor.

A method of using vibration sensors has limitations on the types of containers that can be used, and has various boiling points of containers and foods. Therefore, it may be difficult to accurately determine the boiling time point based solely on the characteristics of the sound data.

### SUMMARY

The disclosure has been made in view of the above problems, and may provide a cooking apparatus using induction heating capable of accurately determining whether the contents of a cooking container are boiling.

The disclosure may further provide a cooking apparatus using induction heating capable of accurately determining the temperature range of the contents of a cooking container.

The disclosure may further provide a cooking apparatus using induction heating capable of improving reliability and user satisfaction by performing optimal control based on the temperature of the contents of a cooking container.

The disclosure may further provide a sensor attachment structure that contributes to improving the accuracy of temperature range determination while reducing the temperature effect caused by heating.

A cooking apparatus using induction heating according to an embodiment of the present disclosure can accurately determine whether the contents of a cooking vessel are boiled by using determination logic using power data together with determination logic using vibration data.

A cooking apparatus using induction heating according to an embodiment of the present disclosure can increase the accuracy of temperature range determination by applying an additional weighting algorithm to the determination logic using vibration data.

A cooking apparatus using induction heating according to an embodiment of the present disclosure includes: a top plate including a heating zone on which a cooking container is placed; a working coil located below the heating zone; an inverter which has a plurality of switching elements, and supplies current to the working coil through an operation of the plurality of switching elements; a first sensor which acquires vibration data in an audible frequency band; and a controller which first determines whether contents of the cooking container are boiling based on the vibration data acquired from the first sensor, secondly determines whether the contents are boiling based on power amount data of the working coil, and determines whether the contents are boiling based on a result of the first determination and a result of the second determination.

The controller includes: a first processor which first determines whether the contents of the cooking container are boiled based on the vibration data acquired from the first sensor; a second processor which secondly determines whether the contents are boiled by measuring power amount of the working coil; and a main processor which finally determines whether the contents are boiled based on the result of the first determination and the result of the second determination.

The second processor calculates an integrated power value by accumulating an output power value of the working coil measured from a driving start time point of the working coil.

The cooking apparatus using induction heating further includes a power sensor that measures a power amount of the heating zone.

The cooking apparatus using induction heating further includes a current sensor measuring the current of the working coil,

The second processor calculates the power amount on the basis of current data of the current sensor.

The first processor includes an AI model which is trained to determine whether boiling has occurred, based on frequency characteristics extracted for each temperature from the acquired vibration data.

The first processor calculates a probability for each temperature class on the basis of the acquired vibration data, and calculates a final probability for each temperature class by reflecting a transition probability corresponding to each probability for each temperature class as a weight.

The transition probability is defined as a probability of transitioning from each temperature range to another temperature range.

The first sensor is arranged on a lower surface of the top plate.

The cooking apparatus using induction heating further includes a bracket attached to the lower surface of the top plate.

A printed circuit board on which the first sensor is mounted is spaced apart from the lower surface of the top plate and is fastened to the bracket, and a ventilation space is formed between the printed circuit board and the lower surface of the top plate.

The bracket includes: a first part attached to the lower surface of the top plate; a second part extending downward from the first part; a plurality of third parts protruding inward from the second part; and a fastening hole formed in the third part.

The third part protrudes from a corner of the second part toward the ventilation space.

The bracket further includes a guide wall arranged on an edge of the first part.

The printed circuit board has an area, in contact with the bracket, from which a copper layer is removed.

A cooking apparatus using induction heating according to an embodiment of the present disclosure includes: a top plate including a heating zone on which a cooking container is placed; a working coil located below the heating zone; an inverter which has a plurality of switching elements, and supplies current to the working coil through an operation of the plurality of switching elements; a first sensor which acquires vibration data in an audible frequency band; and a controller which first determines a temperature range of contents contained in the cooking container, based on the vibration data acquired from the first sensor, secondly determines whether the temperature range, based on power amount data of the working coil, and determines the temperature range, based on a result of the first determination and a result of the second determination.

A cooking apparatus using induction heating according to an embodiment of the present disclosure includes: a top plate including a heating zone on which a cooking container is placed; a working coil located below the heating zone; an inverter which has a plurality of switching elements, and supplies current to the working coil through an operation of the plurality of switching elements; a first sensor which acquires vibration data in an audible frequency band; and a controller which calculates a probability for each temperature class, based on the vibration data acquired from the first sensor, and calculates a final probability for each temperature class by reflecting a transition probability corresponding to each probability for each temperature class as a weight.

The controller includes an AI model which is trained to output the probability for each temperature class, based on frequency characteristics extracted for each temperature from the acquired vibration data.

The controller determines a temperature class having the highest probability value among the final probability for each temperature class as a current temperature.

The controller which first determines whether contents of the cooking container are boiling based on the final probability for each temperature class, secondly determines whether the contents are boiling based on power amount data of the working coil, and determines whether the contents are boiling based on a result of the first determination and a result of the second determination.

### BRIEF DESCRIPTION OF THE DRAWINGS

The above and other objects, features and advantages of the present invention will be more apparent from the following detailed description in conjunction with the accompanying drawings, in which:

FIG. 1 is a perspective view of one side of a cooking apparatus according to an embodiment of the present disclosure;

FIG. 2 is an internal plan view of the cooking apparatus of FIG. 1;

FIG. 3 is an example of an internal block diagram of the cooking apparatus of FIG. 1;

FIG. 4 is an internal block diagram of a cooking apparatus using induction heating according to an embodiment of the present disclosure;

FIG. 5 is a diagram for explaining a boiling determination based on vibration data;

FIGS. 6A to 6C are diagrams for explaining a boiling determination based on vibration data;

FIG. 7 is an internal block diagram of a controller according to an embodiment of the present disclosure;

FIGS. 8 to 12 are diagrams for explaining a sensor and bracket attachment structure according to an embodiment of the present disclosure;

FIGS. 13 and 14 are diagrams for explaining a sensor and bracket attachment structure according to an embodiment of the present disclosure;

FIG. 15 is a diagram for explaining an operation method of a cooking apparatus using induction heating according to an embodiment of the present disclosure;

FIG. 16 is a diagram for explaining an additional boiling determination algorithm according to an embodiment of the present disclosure; and

FIGS. 17 to 20 are diagrams showing classification results before and after applying an algorithm for each temperature profile according to an embodiment of the present disclosure.

### DETAILED DESCRIPTION

Hereinafter, embodiments of the present disclosure will be described in detail with reference to the attached drawings. However, the present disclosure is not limited to these embodiments and can, obviously, be modified in various forms.

Description will now be given in detail according to exemplary embodiments disclosed herein, with reference to the accompanying drawings. For the sake of brief description with reference to the drawings, the same or equivalent components may be denoted by the same reference numbers.

Meanwhile, suffixes such as “module” and “unit” may be used to refer to elements or components. Use of such suffixes herein is merely intended to facilitate description of the specification, and the suffixes do not have any special meaning or function. Accordingly, the terms “module” and “unit” may be used interchangeably.

Furthermore, it will be understood that although the terms first, second, etc. may be used herein to describe various elements, these elements should not be limited by these terms. These terms are only used to distinguish one element from another.

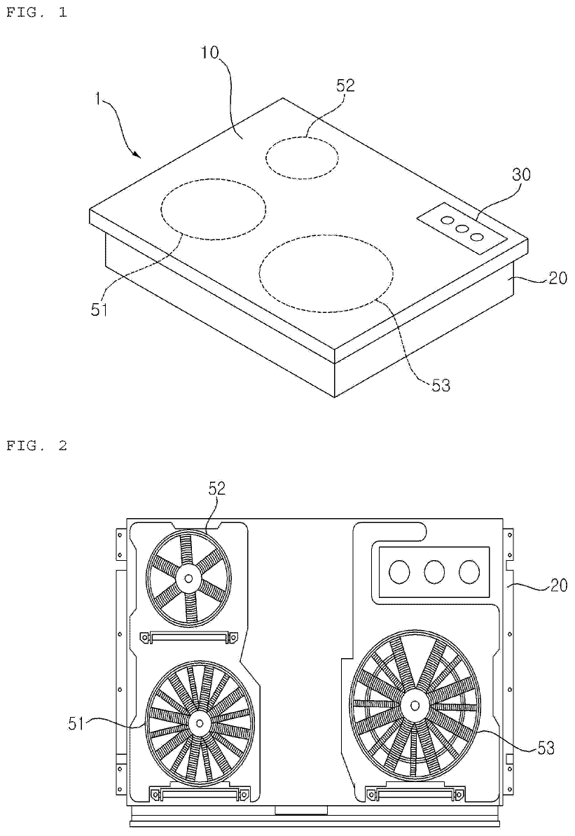

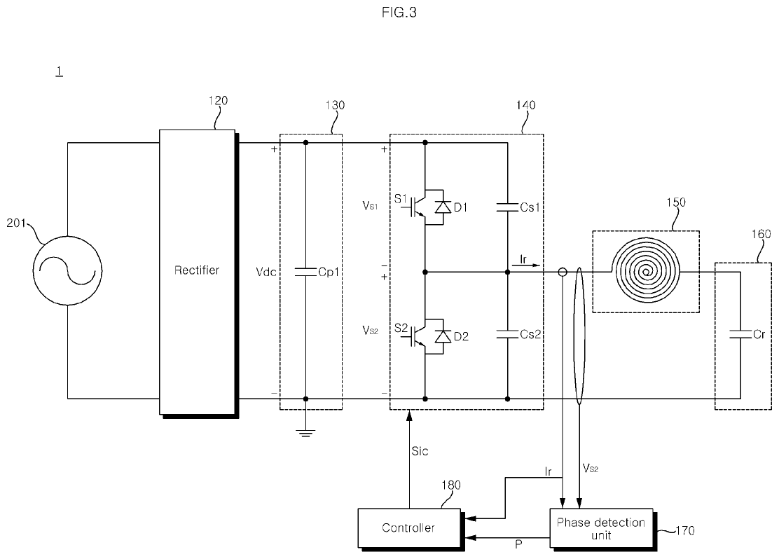

FIG. 1 is a perspective view of one side of a cooking apparatus according to an embodiment of the present disclosure, and FIG. 2 is an internal plan view of the cooking apparatus of FIG. 1.

Referring to FIGS. 1 and 2, a cooking apparatus using induction heating 1 may include a top plate 10 on which a cooking container (not shown) is positioned, a housing 20, and a working coil 51, 52, 53. The drawing illustrates that the cooking apparatus 1 has three working coil 51, 52, 53, but the present disclosure is not limited thereto.

The cooking apparatus using induction heating 1 may heat a cooking container, such as a metal pot, positioned on the top plate 10. The cooking apparatus using induction heating 1 may generate a magnetic field, and some of the magnetic field may pass through the cooking container. At this time, eddy currents may be formed in the cooking container by the magnetic field passing through the cooking container. As the eddy currents flow through the cooking container, heat is generated to heat the cooking container itself, so that the contents within the cooking container can also be heated.

The top plate 10 may be configured to protect the interior of the cooking apparatus using induction heating 1 and support the cooking container. For example, at least the upper portion of the top plate 10 may be formed of tempered glass made of a ceramic material synthesized from various minerals. The top plate 10 may be made of tempered glass, such as ceramic glass, but the material may vary according to the embodiment.

The working coil 51, 52, 53 may be configured to generate a magnetic field for heating the cooking container.

The working coil 51, 52, 53 may be arranged within the cooking apparatus using induction heating 1 surrounded by the top plate 10 and the housing 20. For example, the working coil 51, 52, 53 may be arranged close to the lower portion of the top plate 10.

The working coil 51, 52, 53 may be formed differently from each other. For example, the working coil 51, 52, 53 may have different diameters, winding counts, etc.

Meanwhile, among the entire area corresponding to the top plate 10, each area corresponding to the working coil 51, 52, 53 may be defined as a cooking zone (or heating zone) for heating the cooking container.

Depending on the magnitude, direction, and frequency of the current flowing through the working coil 51, 52, 53, the magnetic field generated through the working coil 51, 52, 53 may vary, and the output of each cooking zone may vary depending on the change in the magnetic field.

The cooking apparatus using induction heating 1 may include an inverter (not shown) that applies a current of a certain frequency to the working coil 51, 52, 53. The working coil 51, 52, 53 may be connected to a single inverter, or may be connected to a plurality of inverters respectively.

A user input unit 30 may be arranged on one side of the top plate 10. For example, a user may use the user input unit 30 to turn the cooking apparatus using induction heating 1 on and off, and adjust the output of each cooking zone.

Meanwhile, the cooking apparatus using induction heating 1 may further include a ferrite (not shown). The ferrite may be formed of a material having a high permeability. The ferrite may be arranged inside the cooking apparatus using induction heating 1.

Ferrite can induce the magnetic field generated from the working coil 51, 52, 53 to flow through the ferrite without being radiated, so that the leakage magnetic field can be reduced and the directionality of the magnetic field can be maximized.

Meanwhile, the ferrite may also be configured to function as a shield that blocks the influence of the magnetic field generated from the working coil 51, 52, 53 or generated from the outside on the internal circuit of the cooking apparatus using induction heating 1.

FIG. 3 is an example of an internal block diagram of the cooking apparatus of FIG. 1.

Referring to FIG. 3, the cooking apparatus using induction heating 1 may include a rectifier 120, a DC capacitor 130, an inverter 140, a working coil 150 (e.g., the working coil 51, 52, 53 of FIG. 1), a resonant unit 160, and/or a controller 180.

The rectifier 120 may rectify and output power supplied from an external power source. The external power source may be a commercial power source 201 that supplies AC power.

The rectifier 120 may convert the AC voltage supplied by the commercial power source 201 into a DC voltage. The commercial power source 201 may be a single-phase AC power source or a three-phase AC power source.

For example, the rectifier 120 may include a bridge diode (not shown) in which a pair of upper-arm and lower-arm diode elements are connected in series, and a total of two or three pairs of upper-arm and lower-arm diode elements are connected in parallel. Meanwhile, the rectifier 120 may further include a plurality of switching elements.

The DC capacitor 130 may be connected to a DC terminal which is an output terminal of the rectifier 120, and may smooth and store the direct current supplied from the rectifier 120. At this time, the voltage applied to both ends of the DC capacitor 130 may also be referred to as a DC voltage Vdc.

The drawing illustrates a single element Cp1 as the DC capacitor 130. However, the present invention is not limited thereto, and a plurality of elements may be provided to ensure element stability.

The inverter 140 may include a plurality of switching elements S1, S2. Through the on/off operations of the switching element S1, S2, the inverter 140 may convert the DC power smoothed and stored in the DC capacitor 130 into AC power of a certain frequency and output it.

For example, if the switching element S1, S2 is an insulated gate bipolar transistor (IGBT), a switching signal Sic generated by a signal of pulse width modulation (PWM) may be output from the controller 180, and input to the gate terminal of the switching element S1, S2. At this time, due to the on/off operation of the switching element S1, S2 according to the switching signal Sic, a high-frequency current may be output from the inverter 140 and flow through the working coil 150.

At this time, when a cooking container (not shown), such as a metal pot, is positioned close to the working coil 150, and the high-frequency current output from the inverter 140 flows through the working coil 150, the magnetic field lines generated by the high-frequency current flowing through the working coil 150 may pass through the cooking container. At this time, the magnetic field lines passing through the cooking container may form eddy currents in the cooking container, and the eddy currents formed in the cooking container may generate heat, thereby heating the cooking container.

The inverter 140 may further include a plurality of snubber capacitors Cs1, Cs2. A plurality of snubber capacitors Cs1, Cs2 may be connected to each of the plurality of switching element S1, S2.

The snubber capacitors Cs1, Cs2 are provided to control and reduce inrush current or transient voltage generated in the switching element S1, S2, and in some cases, may also be used to remove electromagnetic noise.

The snubber capacitors Cs1, Cs2 may influence energy loss during turn-off by controlling the rate of saturation voltage rise during the turn-off of the switching element S1, S2.

The working coil 150 may include a round or circular sector shape, or a polygonal shape such as a triangular or rectangular shape, but is not limited thereto.

The resonant unit 160 may include a resonant capacitor Cr connected between the DC terminal, which is the output terminal of the rectifier 120, and the working coil 150.

For example, the resonant capacitor Cr may have one end connected to the working coil 150 and the other end connected to the DC terminal capacitor 130.

Meanwhile, the resonant frequency of the cooking apparatus using induction heating 1 may be determined based on the capacitance of the resonant unit 160. For example, the resonant frequency of the cooking apparatus using induction heating 1 may be determined based on the inductance of the working coil 150 and the capacitance of the resonant unit 160.

Furthermore, a resonant curve may be formed centered around the resonant frequency determined by the inductance of the working coil 150 and the capacitance of the resonant unit 160. Here, the resonant curve may be a curve representing output power according to frequency.

A quality factor Q may be determined based on the inductance of the working coil 150 and the capacitance of the resonant unit 160, and the resonant curve may be formed differently depending on the quality factor Q.

Therefore, depending on the inductance of the working coil 150 and the capacitance of the resonant unit 160, the cooking apparatus using induction heating 1 may have different output characteristics, and the frequency at which maximum power is output may be referred to as a resonant frequency.

Meanwhile, the resonant unit 160 may be composed of a plurality of resonant capacitors. In this case, the capacitances of the plurality of resonant capacitors may be identical.

For example, one of the plurality of resonant capacitors may have one end that is connected to one end of the DC capacitor 130 and connected to the working coil 150, and another of the plurality of resonant capacitors may have one end that is connected to the other end of the DC capacitor 130 and connected to the working coil 150.

The cooking apparatus using induction heating 1 may utilize a frequency band greater than the resonance frequency, based on the resonance frequency of the resonance curve, and may increase the power level by decreasing the frequency, or may decrease the power level by increasing the frequency.

For example, the cooking apparatus using induction heating 1 may determine any one frequency in the frequency band of 20 kHz to 75 kHz as the switching frequency of the switching element S1, S2 provided in the inverter 140, and control the switching element S1, S2 to alternately turn on and off according to the determined switching frequency.

The controller 180 may be connected to each component provided in the cooking apparatus using induction heating 1, and control the overall operation of each component.

In some embodiment, the cooking apparatus using induction heating 1 may further include a phase detection unit 170.

The phase detection unit 170 may detect a phase difference θ between the voltage applied to the output terminal of the inverter 140 and the current applied to the working coil 150, and output a signal P (hereinafter, a phase signal) corresponding to the phase difference θ.

For example, the phase detection unit 170 may output a pulse signal corresponding to the phase difference θ between the voltage applied to the output terminal of the inverter 140 and the current applied to the working coil 150 as the phase signal P.

At this time, the voltage applied to the output terminal of the inverter 140 may be a switching voltage applied to any one of the plurality of switching element S1, S2. In this drawing, the switching voltage Vs2 applied to the second switching element S2 is exemplified as being applied to the output terminal of the inverter 140, but the present invention is not limited thereto.

The phase detection unit 170 may include a resonance current sensor (not shown) that detects the resonance current Ir applied to the working coil 150, a voltage detection unit (not shown) that detects the voltage Vs2 applied to the output terminal of the inverter 140, and a phase signal output unit (not shown).

The controller 180 may be connected to each component provided in the cooking apparatus using induction heating 1, and may control the overall operation of each component.

The controller 180 may calculate the phase difference θ between the voltage Vs2 applied to the output terminal of the inverter 140 and the resonance current Ir applied to the working coil 150, based on the phase signal P output from the phase detection unit 170.

For example, the controller 180 may receive a phase signal P, which is a pulse signal, from the phase detection unit 170, and, based on the pulse width of the phase signal P, calculate the phase difference θ between the voltage Vs2 applied to the output terminal of the inverter 140 and the resonant current Ir applied to the working coil 150.

The controller 180 may calculate the temperature of a heating target object (the contents of the cooking container) heated by the magnetic field formed by the high-frequency current flowing in the working coil 150.

As the temperature of the heating target object increases, the resonant frequency corresponding to the inflection point of the resonant curve may decrease.

When the temperature of the bottom of the cooking container increases, the electrical conductivity of the cooking container decreases, thereby reducing the eddy current formed in the cooking container.

Meanwhile, the eddy currents formed in the cooking container generate a magnetic field that suppresses the magnetic field generated by the working coil 150. The sum of the magnetic field generated by the working coil 150 and the magnetic field generated by the eddy currents may correspond to the inductance L of the resonant circuit.

At this time, if the temperature at the bottom of the cooking container increases, and the eddy currents formed in the cooking container decreases, the magnetic field generated by the eddy currents also decreases. Consequently, the inductance L of the resonant circuit increases, so that the resonant frequency decreases. Furthermore, if the cooking apparatus using induction heating 1 operates at a fixed frequency (e.g., 40 kHz), the energy transmitted to the cooking apparatus, i.e., the output of the cooking apparatus using induction heating 1, may vary depending on changes in the temperature of the heating target object.

At this time, the output of the cooking apparatus using induction heating 1 is proportional to the magnitude of the resonant current Ir flowing in the resonant circuit, and the cosine value cosθ of the phase difference θ between the resonant current Ir and the voltage Vs2 applied to the resonant circuit. Consequently, if the output of the cooking apparatus using induction heating 1 changes according to the change in the temperature of the heating target object, it may be interpreted that the magnitude of the resonant current Ir and the phase difference θ between the resonant current Ir and the voltage Vs2 applied to the resonant circuit change.

As the temperature of the heating target object increases, the phase difference θ between the resonant current Ir and the voltage Vs2 applied to the resonant circuit may linearly increase. That is, a positive linear relationship exists between the temperature of the heating target object and the phase difference θ between the resonant current Ir and the voltage Vs2 applied to the resonant circuit. Accordingly, the controller 180 may calculate the temperature of the heating target object, based on the phase difference θ between the resonant current Ir and the voltage Vs2 applied to the resonant circuit.

Meanwhile, as the temperature of the heating target object increases, the magnitude of the resonant current Ir may decrease linearly. That is, a negative linear relationship exists between the temperature of the heating target object and the magnitude of the current Ir flowing in the resonant circuit.

Therefore, the controller 180 may calculate the temperature of the heating target object, based on at least one of the magnitude of the resonant current Ir and the phase difference θ between the voltage Vs2 applied to the output terminal of the inverter 140 and the resonant current Ir.

Meanwhile, when the AC current output from the inverter 140 is supplied to the working coil 150, the working coil 150 is driven. When the working coil 150 is driven, a container provided above the working coil 150 is heated.

The magnitude of heat energy supplied to the container may vary depending on the magnitude of power actually generated by the driving of the working coil 150, i.e., the output power value of the working coil.

When a user inputs a heating start command, the controller 180 may determine a required power value of the working coil 150 corresponding to the power level set by a user.

For example, according to an embodiment, the cooking apparatus using induction heating 1 may include a shunt resistor (not shown). The shunt resistor may be arranged between the DC capacitor 130 and the inverter 140. The cooking apparatus using induction heating 1 may include a current sensor (not shown) that senses the magnitude of current, i.e., the current value, flowing through the shunt resistor. The controller 180 may calculate the magnitude of current, i.e., the current value, input to the working coil 150, based on the current value sensed through the shunt resistor.

In an embodiment, the controller 180 may sense the magnitude of the voltage, i.e., the DC link voltage value, applied to both ends of the DC capacitor 130 by using a voltage sensor (not shown). In an embodiment, the controller 180 may calculate the output power value of the working coil 150, based on the current value and the DC link voltage value input to the working coil 150. The controller 180 may calculate the output power value of the working coil 150 by using various known methods.

In an embodiment, the controller 180 may measure the magnitude of the resonant current i.e., the resonant current value of the working coil 150, generated by the working coil 150 when the working coil 150 is driven, by using a resonant current sensor. The controller 180 may adjust the output power value of the working coil 150, based on the resonant current value measured by the resonant current sensor.

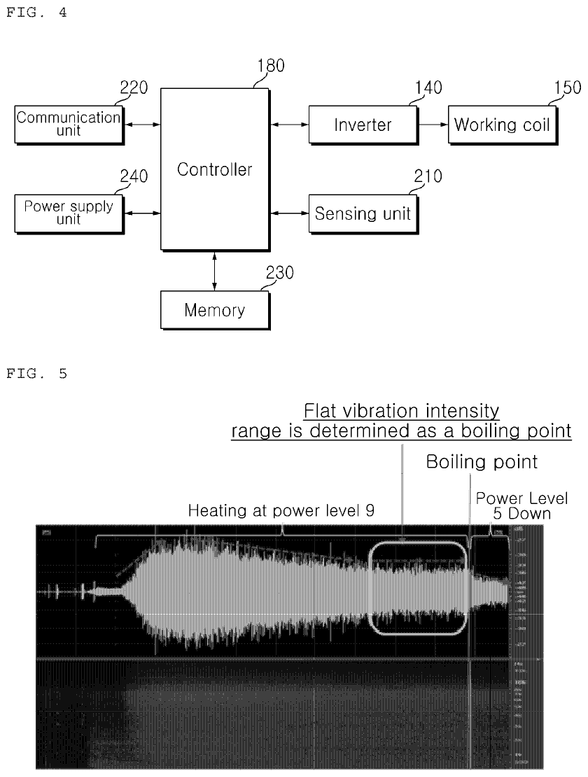

FIG. 4 is an internal block diagram of a cooking apparatus using induction heating according to an embodiment of the present disclosure.

Referring to FIG. 4, the cooking apparatus using induction heating 1 according to an embodiment of the present disclosure may include a working coil 150 that generates a magnetic field for induction heating, an inverter 140 that drives the working coil 150, a power supply unit 240 that supplies power necessary for the operation of each component of the cooking apparatus using induction heating 1, and a controller 180 that controls the overall operation of the cooking apparatus using induction heating 1.

The power supply unit 240 may receive external power and internal power under the control of the processor 180 and supply power necessary for the operation of each component.

The inverter 140 may convert DC power supplied from the power supply unit 240 into AC power and supply it to the working coil 150.

The working coil 150 may be heated by the AC power, and may heat and cook the food inside or above the cooking container by using induction heating.

The controller 180 may control the operation of the cooking apparatus using induction heating 1 according to a user's operating input.

The cooking apparatus using induction heating 1 may further include a memory 230. The memory 230 may store data necessary for the operation and control of the cooking apparatus using induction heating 1. The controller 180 may determine an output profile corresponding to the load amount input by a user and the type of container. The output profile may be pre-stored in the memory 230.

Furthermore, the controller 180 may calculate the temperature of the cooking container and its contents, based on the sensing data of a sensing unit 210. The memory 230 may store sensing data, data for temperature calculation, an Artificial Intelligence (AI) model, and the like. The AI model can be installed in a dedicated processor or the controller 180.

The cooking apparatus using induction heating 1 may further include a communication unit 220 equipped with one or more communication modules for communicating with other devices. The communication unit 220 may communicate with a server or user terminal through wireless or wired communication. The cooking apparatus using induction heating 1 may further include a sensing unit 210 including sensors for sensing and acquiring certain information.

For example, the sensing unit 210 may include one or more temperature sensors for detecting temperature. Furthermore, the sensing unit 210 may further include a resonance current sensor (not shown) for detecting the resonance current Ir applied to the working coil 150 and/or a voltage sensing unit (not shown) for detecting the voltage Vs2 applied to the output terminal of the inverter 140. Alternatively, the sensing unit 210 may include a phase detection unit 170.

The sensing unit 210 may use various types of sensors, such as a voltage sensor, a current sensor, a power sensor, a pressure sensor, and an infrared sensor, to detect whether a cooking container is placed, and detect a relevant working coil corresponding to the position of the cooking container.

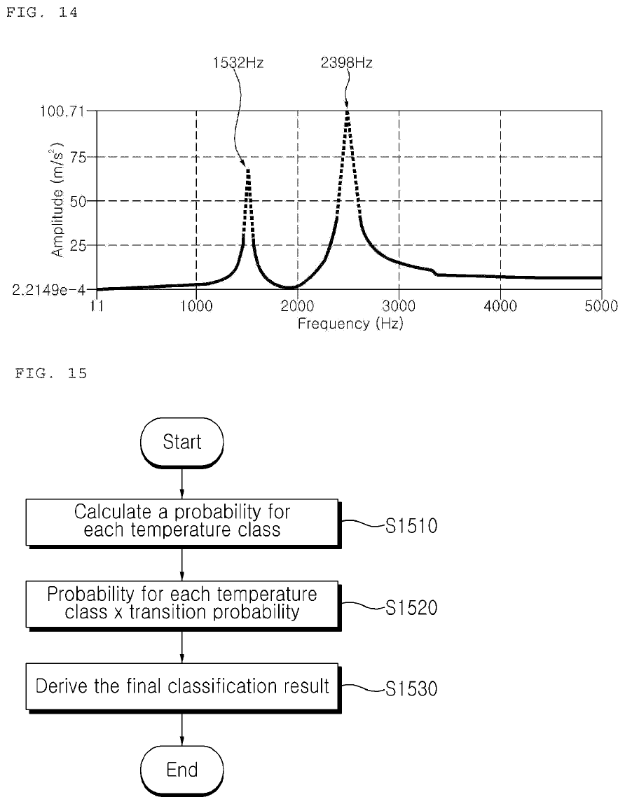

The sensing unit 210 may include a vibration sensor (see 211, etc. of FIG. 11). The controller 180 may perform a Fast Fourier transform (FFT) operation on the vibration data of the vibration sensor 211, frequency-convert the vibration data, and detect boiling of the contents inside the cooking container.

The sensing unit 210 may include at least one of a voltage sensor, a current sensor, and a power sensor. The controller 180 may obtain power amount data from the sensing unit 210 or calculate power amount data on the basis of the sensing data received from the sensing unit 210. The controller 180 may detect boiling of the contents inside the cooking container on the basis of the power amount data.

The cooking apparatus using induction heating 1 may operate according to a temperature profile corresponding to user input. For example, the controller 180 may control heating at power level 9 for a certain heating area, and then reduce the output to power level 5 if it is determined as a boiling state.

The controller 180 may determine whether the contents inside the cooking container are boiling, by applying one of the boiling determinations using vibration data.

In some embodiments, the operation of a home appliance, such as the cooking apparatus using induction heating 1 described herein, may be performed on a server. For example, a server may receive data from the cooking apparatus using induction heating 1, process the received data, and determine the boiling, the temperature range, etc.

The boiling detection method of the prior art utilizes a temperature sensor attached to the lower portion of a top plate cooking zone and a vibration sensor attached to the surrounding area.

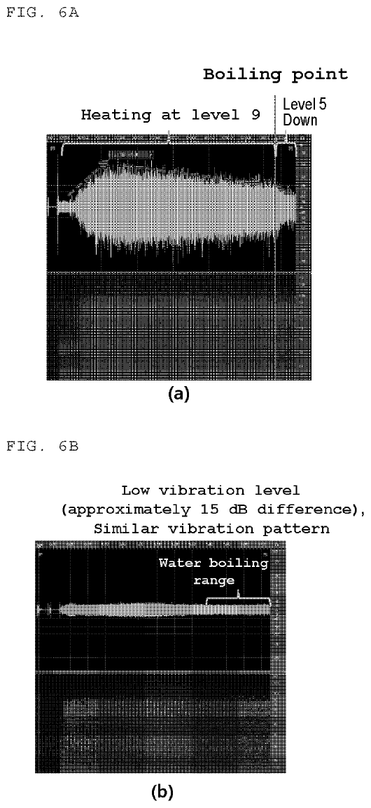

FIG. 5 is a diagram for explaining a boiling determination based on vibration data.

Referring to FIG. 5, in the prior art, a vibration sensor may measure audible sound vibrations, when food is heated in a heating zone on the top plate.

As shown in FIG. 5, the change in the intensity of the vibration frequency occurs according to the boiling stage of the food, and the key to the prior art is to detect this change in frequency intensity.

Referring to FIG. 5, when food is boiling, bubbles are initially formed and the vibration gradually increases, and then, when the food reaches a specific temperature, the vibration intensity decreases.

Finally, when the food is boiled, the vibration intensity becomes constant. However, the above mentioned situation applies only to specific containers and does not apply to most containers.

Conventional technology may convert audible sound vibration data into a frequency power spectrum by using a Fourier transform operation. The controller 180 may detect the maximum vibration level from audible sound vibration measured over time. Furthermore, a flat slope vibration level range may be detected and a flat vibration intensity range may be determined as a boiling point.

Meanwhile, a temperature sensor may be used to measure the temperature associated with the heating zone in use. If the temperature associated with the currently used heating zone reaches a preset temperature, boiling may be determined.

Meanwhile, when heating food in a first heating zone and a second heating zone, the detection of the flat slope vibration level range may be performed independently of the heating zone distinction.

The first heating zone may be identified based on information from the temperature sensor indicating a higher temperature in the independently detected flat slope vibration level.

If the detected flat slope vibration level is higher than the initial vibration level, the first heating zone may be determined to have boiled. When the initial vibration level is detected, the boiling state may be determined based on the sound level relationship between the initial state and the boiling state. Furthermore, the boiling state may be determined based on the temperature slope determined over time.

Meanwhile, the containers used are very diverse, and the types and amounts of food contained in each container also vary. It is difficult to accurately estimate the temperature of food contained inside various containers using the temperature sensor under the top plate.

Depending on the container type, food type, and amount of food, there is a significant error between the actual food temperature and the temperature sensor under the induction top plate. Therefore, the temperature sensor can only be used for auxiliary purposes.

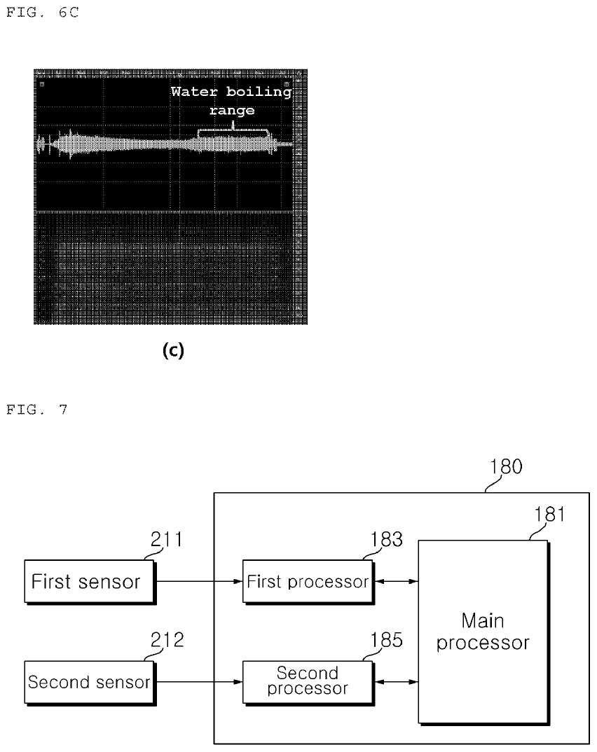

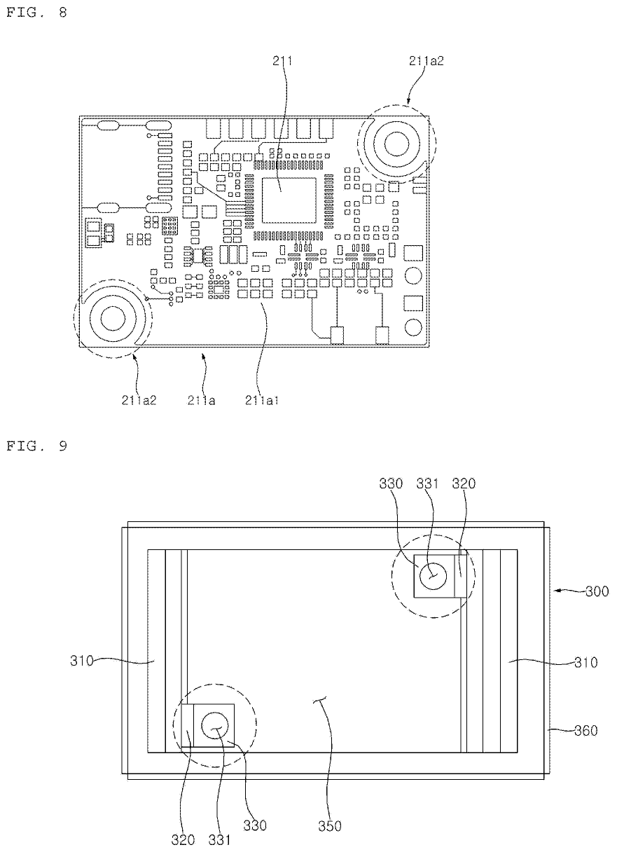

FIGS. 6A to 6C are diagrams for explaining a boiling determination based on vibration data, and illustrates various patterns that vary depending on the container type, food type, and amount of food.

Referring to FIG. 6A, when the food volume is small, the vibration intensity slope may decrease during the actual boiling range. The slope then flattens out after a considerable time. This indicates a case where the heat should be reduced at the boiling point, but this timing is missed.

Referring to FIG. 6B, depending on the container, the vibration may be so small that it may be difficult to perceive the change in boiling vibration.

Referring to FIG. 6C, depending on the container, the vibration intensity may increase at the boiling point.

Therefore, the prior art has limitations in that it could only operate properly in specific containers, and only operate with a specific food type, such as water or thin soups.

The top plate 10 may be provided with one or more heating zones where cooking containers are placed. A working coil 150 may be positioned below each heating zone. The controller 180 may control the inverter 140 that supplies current to the working coil 150 to heat the cooking container above the heating zone.

When food in the cooking container is heated, the sound varies depending on the boiling stage, and the sound at the boiling point can be distinguished.

The sensing unit 210 includes a first sensor 211 that acquires vibration data in the audible frequency band. The first sensor 211 may be a vibration sensor.

The controller 180 may include an AI model trained to output a probability for each temperature class, based on frequency characteristics extracted for each temperature from the vibration data acquired by the first sensor 211.

The AI model may output a probability for each temperature class when vibration data is input, and the controller 180 may determine the temperature class having the highest probability value among final probabilities for each temperature class as a current temperature range.

The controller 180 may initially determine the temperature range of the contents of the cooking container, based on the vibration data acquired by the first sensor 211.

Meanwhile, the sensing unit 210 may include one or more temperature sensors (not shown). The sensing unit 210 may measure vibration data simultaneously with the food temperature. The controller 180 may acquire vibration/sound data and temperature data for each boiling stage through the sensing unit 210.

The cooking zone to which power is supplied becomes a cooking zone that measures the boiling data. As it approaches the food boiling stage, the amount of power input remains almost constant.

The controller 180 may classify the current temperature range into one of a plurality of preset temperature ranges on the basis of the vibration frequency.

The controller 180 may include an AI model that classifies the current temperature range into one of a plurality of preset temperature ranges on the basis of the vibration frequency.

The controller 180 may extract frequency characteristics from the measured vibration data according to the food temperature. The controller 180 may extract the frequency characteristics in specific time units. The controller 180 may include an AI model trained using the extracted frequency characteristics.

The AI model may determine the boiling vibration frequency in real time. To prevent errors, the AI model may check the temperature level several times at specific time units.

When determining based solely on the vibration frequency, the determined temperature may differ significantly from the actual temperature. To prevent this, an additional algorithm may be applied to more accurately determine the current temperature range and whether boiling has occurred.

To determine the boiling point of various containers and foods, it may not be easy to accurately distinguish the boiling time point based solely on sound data characteristics. The present disclosure applies a separate weighting algorithm to existing algorithms to enhance the accuracy of the boiling point determination.

In an embodiment, the controller 180 may perform a second determination of the temperature range on the basis of the power amount data of the working coil 150.

Finally, the controller 180 may perform a final determination of the temperature range on the basis of the first determination result and the second determination result.

Furthermore, the controller 180 may firstly determine whether the contents of the cooking container have boiled on the basis of the final probability for each temperature class, secondly determine the boiling on the basis of the power amount data of the working coil 150, and finally determine the boiling on the basis of the first determination result and the second determination result.

By utilizing different types of determination logic, it is possible to more accurately determine whether the contents of a cooking container are boiling. Specifically, by using determination logic using vibration data together with determination logic using power amount data, it is possible to accurately determine whether the contents of a cooking container are boiling.

In an embodiment, the controller 180 may apply different weights to the first determination result using vibration data and the second determination result using power amount data, and use the result having the higher value as a final determination.

In an embodiment, the controller 180 may apply different weights in a specific range. For example, in a range where the temperature is risen and about to reach a boiling state, a higher weight may be applied to the first determination result using vibration data.

Furthermore, by concurrently employing additional logic that applies weight to the first determination result and logic using power amount, the accuracy of temperature range and boiling state determinations can be further enhanced.

In another embodiment, the accuracy of temperature range and boiling state determination can be enhanced by applying additional logic that applies weight to the first determination results.

The controller 180 may accurately determine whether the contents of the cooking container are boiling by reflecting additional logic that applies a temperature range transition probability as a weight to the determination logic using vibration data. The transition probability may be defined as a probability of transitioning from each temperature range to another temperature range.

The controller 180 calculates probabilities for each temperature class on the basis of vibration data acquired from the first sensor 211, and may calculate the final probability for each temperature class by reflecting the transition probability corresponding to each probability for each temperature class as a weight.

According to an embodiment of the present disclosure, a weighting algorithm is added to perform the final determination. The weighting algorithm determines by comparing the temperature value determined as the current vibration frequency with the previous temperature value.

The transition probability, which may change from a temperature range of a first time point to a temperature range of a second time point, may be reflected in the temperature value determined as a weight.

By using the transition probability as a weighting algorithm, situations where the unit value is lower than the previous temperature value or suddenly becomes too low due to erroneous determination are prevented.

Furthermore, the controller 180 may classify the current temperature range into one of a plurality of preset temperature ranges on the basis of power amount data.

The controller 180 may utilize the classification result based on vibration frequency and the power amount data to detect the location of cooking zone and detect boiling.

FIG. 7 is an internal block diagram of a controller according to an embodiment of the present disclosure.

Referring to FIG. 7, the controller 180 may include one or more processors 181, 182, and 183. The controller 180 may include a main processor 181 that controls the overall operation of the cooking apparatus using induction heating 1.

The controller 180 may further include a first processor 183.

The first processor 183 may determine the current temperature range on the basis of vibration data acquired from the first sensor 211.

Based on the vibration data acquired from the first sensor 211, the first processor 183 may firstly determine whether the contents of the cooking container have boiled.

The first processor 183 may extract frequency characteristics from the vibration data acquired through the first sensor 211. The first processor 183 may extract frequency characteristics for each temperature.

The first processor 183 may include an AI model trained to determine whether boiling has occurred, on the basis of the frequency characteristics extracted for each temperature.

The first processor 183 may calculate a probability for each temperature class, on the basis of the vibration data acquired through the first sensor 211.

According to an embodiment, the first processor 183 may calculate the final probability for each temperature class, by reflecting the transition probability corresponding to each probability for each temperature class as a weight.

The controller 180 may further include a second processor 185. The second processor 185 may measure the power amount of the working coil 150 to determine the current temperature range. The second processor 185 may measure the power amount of the working coil 150 to secondarily determine whether boiling has occurred.

The cooking apparatus using induction heating 1 may include a second processor 185 capable of measuring the power amount input for each cooking zone (heating zone) on which the cooking container is placed. The second processor 185 may be a power controller.

The second processor 185 may determine the current temperature range on the basis of sensing data of the second sensor 212.

The sensing unit 210 may include a power sensor that measures the power amount of the heating zone, and the second sensor 212 may be a power sensor.

The power amount data may be an integrated power value. The second sensor 212 may calculate the integrated power value by accumulating the output power value of the working coil 150 measured from the start time point of the driving of the working coil 150.

In this specification, the integrated power value refers to a value calculated by accumulating the output power value of the working coil 150 measured from the start time point of the driving of the working coil 150 by a preset time unit.

In other words, the accumulated power value refers to the amount of power consumed by the working coil 150 from the start time point of the driving of the working coil 150 to a specific time point.

The sensing unit 210 may include a current sensor that measures the current of the working coil 150, and the second sensor 212 may be a current sensor. In this case, the second processor 185 may calculate the amount of power on the basis of the current data of the current sensor. In addition, the second processor 185 may measure the calculated power amount to secondarily determine whether boiling has occurred.

The containers used in induction cooking can be broadly classified into four types (enamel, stainless steel, cast iron, and disc).

Vibration frequency data is acquired by boiling various foods for each container. Frequency characteristics at the boiling time point are extracted from the acquired vibration frequency.

Similarly, the power amount data consumed in the cooking zone at the boiling time point is acquired and compared with the temperature conditions at the boiling time point.

This data may be trained using an AI algorithm, and an AI model (classifier) for the boiling time point may be created.

The main processor 181 may perform a final determination of whether boiling has occurred, based on the first determination results of the first processor 183 and the second determination results of the second processor 185.

The main processor 181 combines the frequency characteristics at the boiling point with the power amount at the boiling point to enhance determination accuracy.

The cooking zone receiving power is a cooking zone that measures the boiling data. As it approaches the food boiling stage, the amount of input power remains nearly constant. The cooking zone location may be determined and the boiling may be detected by using the AI vibration frequency classifier results and power amount data.

The main processor 181 may select the result having the higher value among the first determination result of the first processor 183 and the second determination result of the second processor 185 as a final result.

Alternatively, the main processor 181 may weight the first determination result of the first processor 183 and the second determination result of the second processor 185, and select the result having the higher value as a final result.

When detecting boiling using only existing vibration data, accuracy may be reduced. If the magnitude of the vibration frequency remains constant at the moment of boiling, it can be determined when the intensity is equal to or greater than a certain magnitude. Therefore, boiling detection is only possible in specific containers, and possible only for thin foods such as water.

However, by utilizing the present disclosure, the evaluation is based not on vibration intensity but on combining the characteristic of vibration frequency when food is boiling, through AI, with the power amount input to the container receiving the food. Thus, the restrictions on the containers and food types are significantly reduced, and accuracy is further improved.

Meanwhile, unlike FIG. 7, the first processor 183 and/or the second processor 185 may be separately installed outside the controller 180.

The controller 180 receives audible frequency band input through the first sensor 211, and then distinguishes the boiling sound by using an AI algorithm. The hardware and software of the first sensor 211 are designed to receive data over a wide frequency band covering the entire frequency band of the boiling sound.

The first sensor 211 is attached to the top plate 10, and a separate bracket is manufactured and attached to ensure that the sound frequency band is received without distortion.

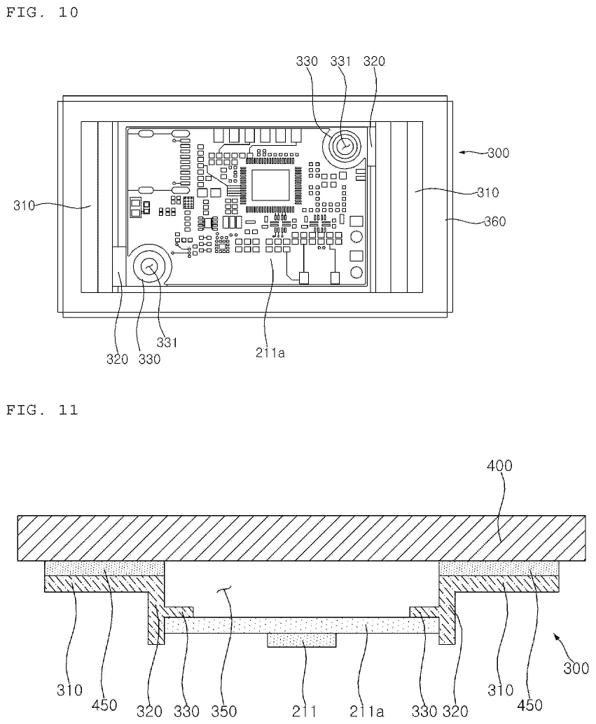

FIGS. 8 to 12 are drawings for explaining a sensor and bracket attachment structure according to an embodiment of the present disclosure.

FIG. 8 illustrates an on-device module printed circuit board (PCB) 211a on which the first sensor 211 is mounted, and FIG. 9 illustrates a bracket 300.

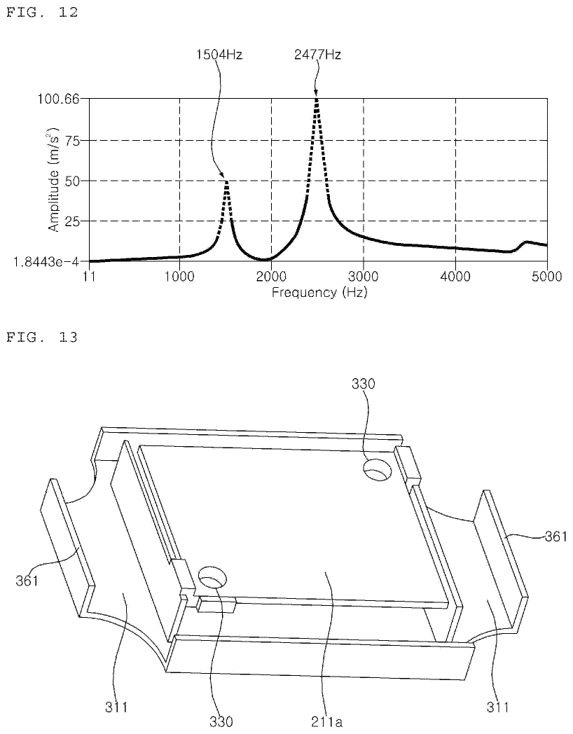

FIG. 10 illustrates the printed circuit board 211a on which the first sensor 211 is mounted and the bracket 300, as viewed from below. FIG. 11 is a side view of the bracket 300 and the printed circuit board 211a that are attached to the lower surface 400 of the top plate 10.

Referring to FIGS. 8 to 11, the first sensor 211 may be arranged on the lower surface 400 of the top plate 10.

When heated, the top plate 10 may become very hot, and heat may be transferred to the first sensor 211. The high temperature of the top plate 10 may cause malfunction or damage to the printed circuit board 211a on which the first sensor 211 is installed. When a large cooking container is used near the cooking zone, the temperature effect increases, and a sensor having an expensive, high-temperature specification is required.

The bracket 300 is attached to the lower surface 400 of the top plate 10, and the printed circuit board 211a on which the first sensor 211 is installed may be spaced apart from the lower surface 400 and fastened to the bracket 300.

A ventilation space 350 may be formed between the printed circuit board 211a and the lower surface 400 of the top plate 10. Since there is a ventilation space 350 through which air can pass, the heat of the top plate 10 is not directly transferred to the printed circuit board 211a. Even if heat is transferred, it is easily dissipated by the air in the ventilation space 350.

By using the bracket 300, the installation of the first sensor 211 is easy, and the heat effect during cooking can be minimized. Since the heat effect is minimized, a low-cost model may be used without the need to deal with excessively high temperatures, thereby reducing manufacturing costs.

The bracket 300 may include a first part 310 attached to the lower surface 400 of the top plate 10. The first part 310 may be attached to the lower surface 400 by using a silicone bond 450.

The bracket 300 may include a second part 320 extending downward from the first part 310, and a plurality of third parts 330 protruding inward from the second part 320.

The third part 330 may protrude from a corner of the second part 320 toward the ventilation space 350. A fastening hole 331 is formed in the third part 330, and may be fastened to the printed circuit board 211a by using a fastening member such as a screw.

In order to minimize heat transfer from the top plate 10 to the bracket 300 and the printed circuit board 211a, a ventilation space 350 is secured, and a coupling portion is minimized when screw-coupled. The third part 330, which is the coupling portion, is limited to the distal ends of both corners of the bracket 300, thereby minimizing the coupling portion when screw-coupled. Accordingly, heat transferred from the top plate 10 to the bracket 300 is transferred to the printed circuit board 211a only through a narrow coupling portion.

In addition, the printed circuit board area 211a2 coupled to the bracket 300 removes a copper layer that facilitates heat transfer. The copper layer is removed from the surface of the printed circuit board 211a that contacts the bracket 300, thereby preventing heat transfer to components within the printed circuit board 211a. That is, the copper layer on the printed circuit board 211a is separated from the internal circuit 211a1 to prevent heat transfer.

Conventionally, rubber-based materials have been used for heat insulation. Although this method blocks heat, when receiving vibration data from the top plate, high-frequency signals are greatly attenuated, so that a loss occurs in detecting accurate vibration characteristics.

The present disclosure directly couples the printed circuit board 211a and the bracket 300 without a separate insert, and minimizes a coupled portion, and the printed circuit board 211a separates or removes the copper layer of a coupling portion to prevent efficient heat transfer.

According to the present disclosure, a sensor attachment structure that helps improve the accuracy of temperature range determination while reducing the temperature effect due to heating may be provided.

The first sensor 211 must be able to sense all main frequencies of boiling vibration. Therefore, when attaching the first sensor 211 to the top plate 10, a specific mechanical resonance point must not be within the sensed frequency range.

To avoid a specific mechanical resonance point, the first sensor 211 is mounted on a separate bracket 300 and attached to the top plate. The bracket 300 is designed to avoid a mechanical resonance point.

The bracket 300 may further include a guide wall 360 arranged on the edge of the first part 310.

For example, the frequency band for boiling detection may be up to 1.5 kHz. In this case, it is important that the first sensor 211 may accurately receive vibration frequencies within 1.5 kHz without distortion.

Two structural designs are developed to avoid low-frequency resonance within 1.5 kHz at the outer edge of the bracket 300.

A guide wall 360 is placed on the outer edge of the bracket 300 to prevent bending and block low-frequency resonance.

FIG. 12 illustrates the results of a structural analysis of the bracket 300 including the guide wall 360. Referring to FIG. 12, it may be confirmed that low-frequency resonance does not occur within 1.5 kHz.

Furthermore, by reducing the mass effect at the corner, resonance occurring near 1.5 kHz may be shifted to a higher frequency band.

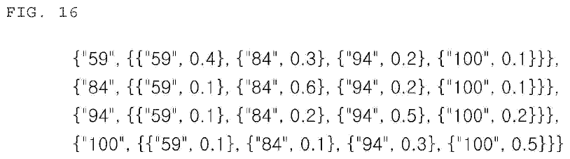

FIGS. 13 and 14 are diagrams for explaining a sensor and bracket attachment structure according to an embodiment of the present disclosure.

FIG. 13 illustrates the bracket 300 with a corner portion 311 removed. As the corner portion 311 is removed, the guide wall 360 and a portion of the first part 360 may be removed.

FIG. 14 illustrates the structural analysis results of the bracket 300 with the corner portion 311 removed. Referring to FIG. 14, it may be confirmed that the resonance occurring near 1.5 kHz has shifted to a farther frequency band.

Existing temperature classification model performs classification independently without considering the correlation between temperature classes. However, in real data, correlations between classes may exist, and utilizing this correlation may improve classification accuracy.

The present disclosure may improve the performance of a classification model by reflecting the correlation between temperature classes.

FIG. 15 is a diagram for explaining an operation method of a cooking apparatus using induction heating according to an embodiment of the present disclosure, and FIG. 16 is a diagram for explaining an additional boiling determination algorithm according to an embodiment of the present disclosure.

First, the controller 180 may calculate a probability for each temperature class, on the basis of frequency characteristics extracted for each temperature from vibration data acquired by the first sensor 211 (S1510).

The calculation of the probability for each temperature class may be performed in a pre-trained AI model. The AI model may output the probability for each temperature class when vibration data is input.

For example, a temperature class may include a 59-degree range of 0° C. to 59° C., an 84-degree range of 60° C. to 84° C., a 94-degree range of 85° C. to 94° C., and a 100-degree range of 95° C. to 100° C. In this case, the AI model may calculate the probability that the current temperature range is 59 degrees, the probability that the current temperature range is 84 degrees, the probability that the current temperature range is 94 degrees, and the probability that the current temperature range is 100 degrees, respectively.

The controller 180 may determine the temperature class having the highest probability value among the final probabilities for each temperature class as a current temperature range.

The controller 180 may first determine the temperature range of the contents of the cooking container on the basis of the vibration data acquired from the first sensor 211.

The controller 180 may apply a weight that reflects the correlation between classes (S1520).

FIG. 16 illustrates a matrix representing a transition probability between classes. The matrix represents the probability of transitioning from each class to another class.

Referring to FIG. 16, when the temperature range at a first time point is 59 degrees, the probability that the temperature range at a second time point is 59 degrees is 0.4, the probability that it is 84 degrees is 0.3, the probability that it is 94 degrees is 0.2, and the probability that it is 100 degrees is 0.1.

When the temperature range at the first time point is 84 degrees, the probability that the temperature range at the second time point is 59 degrees is 0.1, the probability that the temperature range at the second time point is 84 degrees is 0.6, the probability that the temperature range at the second time point is 94 degrees is 0.2, and the probability that the temperature range at the second time point is 100 degrees is 0.1.

When the temperature range at the first time point is 94 degrees, the probability that the temperature range at the second time point is 59 degrees is 0.1, the probability that the temperature range at the second time point is 84 degrees is 0.2, the probability that the temperature range at the second time point is 94 degrees is 0.5, and the probability that the temperature range at the second time point is 100 degrees.

When the temperature range at the first time point is 100 degrees, the probability that the temperature range at the second time point is 59 degrees is 0.1, the probability that the temperature range at the second time point is 84 degrees is 0.1, the probability that the temperature range at the second time point is 94 degrees is 0.3, and the probability that the temperature range at the second time point is 100 degrees is 0.5.

The controller 180 may multiply the probability for each temperature range by the transition probability to reflect the weight (S1520). For example, when the current temperature range is 94 degrees, the probability of being in the 59 degree range may be multiplied by a weight of 0.1, the probability of being in the 84 degree range by a weight of 0.2, the probability of being in the 94 degree range by a weight of 0.5, and the probability of being in the 100 degree range by a weight of 0.2.

The controller 180 may apply a weight to the probability value for each current class on the basis of past class value (S1520), and derive the final classification result (S1530). This may improve classification accuracy by reflecting the correlation between classes.

The controller 180 may select the class having the highest probability as the final classification result.

Meanwhile, the controller 180 may determine the 100 degree range as a boiling state.

The present disclosure may improve the performance of a classification model by reflecting the correlation between temperature classes. By applying a transition probability matrix, the classification model may consider the correlation between each class and derive more accurate classification results. This is particularly useful in a dataset where transition between classes occur frequently. The performance of the classification model is enhanced by applying a weight that reflects the correlation between classes. By defining a transition probability matrix and applying it to the output of the classification model to derive the final classification result, and enhance the classification accuracy.

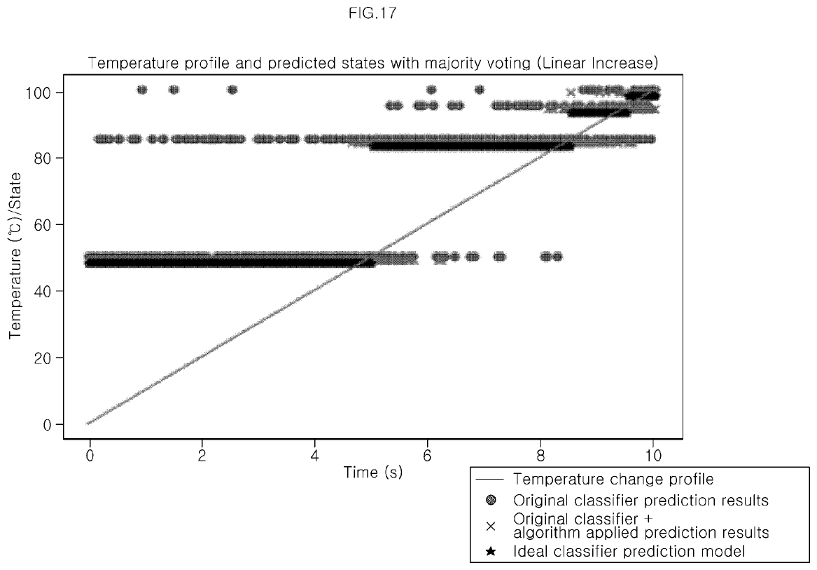

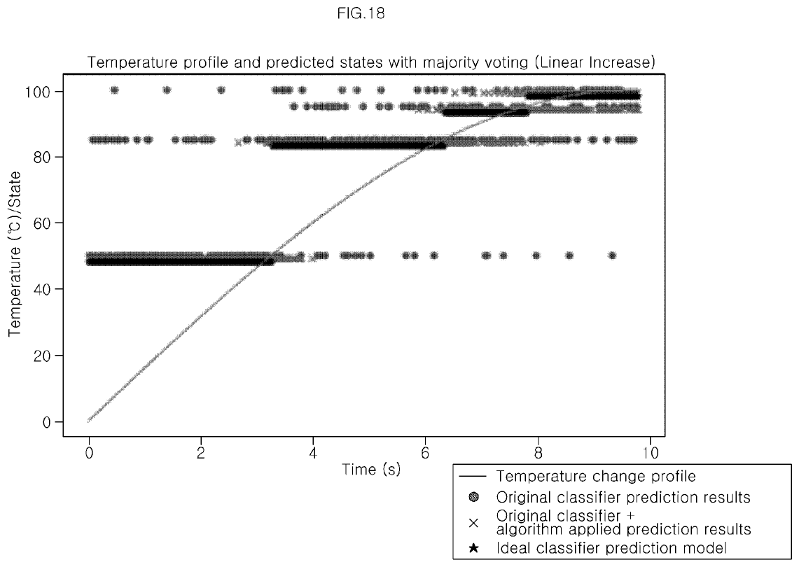

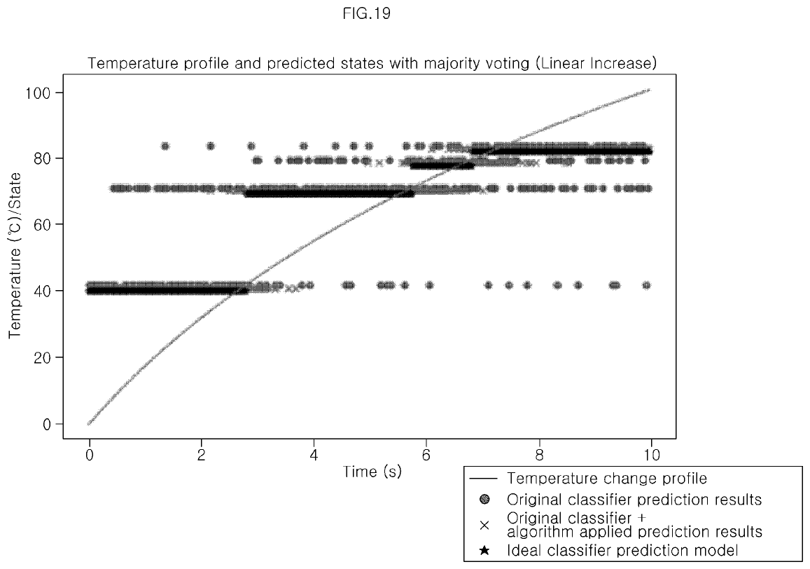

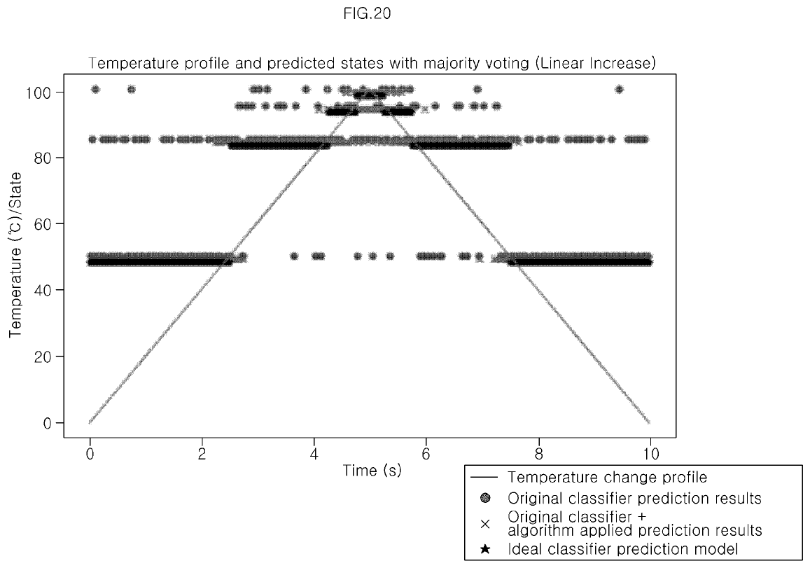

FIGS. 17 to 20 are diagrams showing classification results before and after applying an algorithm for each temperature profile according to an embodiment of the present disclosure. More specifically, the diagrams illustrate the results before and after applying an algorithm that applies transition probability weights to vibration data analysis and adds a secondary determination using power data.

In FIGS. 17 to 20, the X-axis represents the time axis, and the Y-axis represents the temperature axis. Furthermore, in FIGS. 17 to 20, the solid line represents temperature change over time, the star shape represents the prediction model of the ideal classifier, and the dot and the X-shape represent the prediction results before and after applying the algorithm according to an embodiment of the present disclosure, respectively.

According to the present disclosure, a temperature range prediction result superior to a case where the temperature range is predicted using only vibration data can be obtained. Accordingly, reliability and customer satisfaction may be enhanced by performing optimal control depending on the temperature of the contents of the cooking container.

According to at least one embodiment of the present disclosure, it is possible to accurately determine whether the contents of a cooking container are burning by using different types of determination logic.

According to at least one embodiment of the present disclosure, it is possible to accurately determine whether the contents of a cooking container are burning by using determination logic using power amount data together with determination logic using vibration data.

According to at least one embodiment of the present disclosure, it is possible to accurately determine whether the contents of a cooking container are burning by using additional logic that applies the temperature range transition probability as a weight to the determination logic using vibration data, thereby accurately determining whether the contents of the cooking container is boiling.

According to at least one embodiment of the present disclosure, reliability and satisfaction can be improved by performing optimal control depending on the temperature of the contents of the cooking container.

According to at least one embodiment of the present disclosure, it is possible to provide a sensor attachment structure that helps improve the accuracy of temperature range determination, while reducing the temperature effects caused by heating.

Although the present disclosure has been described with reference to specific embodiments shown in the drawings, it is apparent to those skilled in the art that the present description is not limited to those exemplary embodiments and is embodied in many forms without departing from the scope of the present disclosure, which is described in the following claims.

The contents described above may be implemented as one or more computer programs, or as computer-readable storage media as a combination of one or more of the foregoing.

The functions of the elements disclosed herein may be implemented using a circuit or processing circuit including a general-purpose processor, a special-purpose processor, an integrated circuit, an application-specific integrated circuits (ASIC), a conventional circuit, and/or a combination thereof. This circuit may be a processor configured or programmed to perform a disclosed function.

A processor may be considered as a processing circuit or circuit because it includes transistors and other circuits. The circuit, unit, or means described herein may be hardware that performs or is programmed to perform the functions described in the detailed description. The hardware may be hardware disclosed herein or other known hardware, and may be hardware programmed or configured to perform the functions described in the detailed description. If the hardware is a processor, which may be considered as a type of circuit, the circuit, means, or unit may be a combination of hardware and software used to configure the hardware and/or the processor. Furthermore, the computer storage medium may be non-transitory computer storage medium. For example, it may be executable by a cloud server-based system.

Furthermore, the data described in the specification may be computed or performed in various environments, such as a cloud server-based system, an on-device system, or a distributed server system (a plurality of servers). The data may be distributedly processed in a cloud server or executed locally on an on-device processor, and the results of the processing in each environment may be stored in non-volatile memory.

A server (or server system) may be configured to transmit output data for display on a specific electronic device, home appliance, or user display. As another example, the server may configure output data as a set of computer-readable instructions, such as one or more computer programs. The computer programs may be written in any type of programming language and according to any programming paradigm, such as declarative, procedural, assembly, object-oriented, data-oriented, functional, or imperative. The computer programs may be written to perform one or more different functions and operate under a computing environment, such as across physical devices, virtual machines, or a plurality of devices. The computer programs may implement the functions described herein, for example, as performed by a system, engine, module, or model.

A server computing device may be implemented on one or more devices having one or more processors in one or more locations. A computing device or server computing device may be communicatively connected to one or more storage devices via a network. The storage devices may be a combination of volatile and non-volatile memory, and may be located in the same or different physical locations as the computing devices. For example, the storage device may include various storage drives, such as drive, solid-state drive, tape drive, optical storage, memory card, ROM, RAM, DVD, CD-ROM, or read-only media inside the drive. That is, the storage devices may be any type of non-transitory computer storage capable of storing long-term dedicated data.

Electronic devices, such as home appliances, and server computing devices may be connected to one or more storage devices via a network. These storage devices may be a combination of volatile and non-volatile memory, and may or may not be located in the same physical location as the computing devices.

The server computing device may include one or more processors and memory. Memory stores information accessible to the processor, and may include data that may be processed, stored, or modified by instructions executed by the processor. Furthermore, this memory may consist of volatile and non-volatile memory. The processor may include a central processing unit (CPU), a graphics processing unit (GPU), a field programmable gate array (FPGA), an application-specific integrated circuit (ASIC), or a tensor processing unit (TPU).

Instructions may be configured to perform specific operation when the processor is executed and may be stored in an object code format or an interpretable script format. These instructions may be used to implement a system, and may be executed on a local or remote processor. Data may be retrieved, stored, or modified according to the instructions, and may be configured in a database, JSON, YAML, or XML format.

Electronic devices, including home appliances and hubs, may be configured similarly to server computing devices. In addition to a processor, memory, instructions, and data, electronic devices including home appliances and hubs may include user input and output devices. The server computing device may transmit data to the electronic device, and the electronic device may display a portion of the received data via a display. Furthermore, data transmission and communication between the server computing device and the electronic device is possible via a network such as Bluetooth, Wi-Fi, wired, and wireless network, various protocols and connection methods can be supported, direct and indirect communication between computing devices is possible, and various protocols and connection methods can supported.

What is claimed is:

1. A cooking apparatus using induction heating comprising:
a top plate including a heating zone on which a cooking container is placed;
a working coil located below the heating zone;
an inverter which has a plurality of switching elements, and supplies current to the working coil through an operation of the plurality of switching elements;
a first sensor which acquires vibration data in an audible frequency band; and
a controller which first determines whether contents of the cooking container are boiling based on the vibration data acquired from the first sensor, secondly determines whether the contents are boiling based on power amount data of the working coil, and determines whether the contents are boiling based on a result of the first determination and a result of the second determination.

2. The cooking apparatus using induction heating of claim 1, wherein the controller comprises:
a first processor which first determines whether the contents of the cooking container are boiled based on the vibration data acquired from the first sensor;
a second processor which secondly determines whether the contents are boiled by measuring power amount of the working coil; and
a main processor which finally determines whether the contents are boiled based on the result of the first determination and the result of the second determination.

3. The cooking apparatus using induction heating of claim 2, wherein the second processor calculates an integrated power value by accumulating an output power value of the working coil measured from a driving start time point of the working coil.

4. The cooking apparatus using induction heating of claim 2, further comprising a power sensor that measures a power amount of the heating zone.

5. The cooking apparatus using induction heating of claim 2, further comprising a current sensor measuring the current of the working coil,
wherein the second processor calculates the power amount on the basis of current data of the current sensor.

6. The cooking apparatus using induction heating of claim 2, wherein the first processor comprises an AI model which is trained to determine whether boiling has occurred, based on frequency characteristics extracted for each temperature from the acquired vibration data.

7. The cooking apparatus using induction heating of claim 2, wherein the first processor calculates a probability for each temperature class on the basis of the acquired vibration data, and calculates a final probability for each temperature class by reflecting a transition probability corresponding to each probability for each temperature class as a weight.

8. The cooking apparatus using induction heating of claim 7, wherein the transition probability is defined as a probability of transitioning from each temperature range to another temperature range.

9. The cooking apparatus using induction heating of claim 1, wherein the first sensor is arranged on a lower surface of the top plate.

10. The cooking apparatus using induction heating of claim 9, further comprising a bracket attached to the lower surface of the top plate,
wherein a printed circuit board on which the first sensor is mounted is spaced apart from the lower surface of the top plate and is fastened to the bracket, and a ventilation space is formed between the printed circuit board and the lower surface of the top plate.

11. The cooking apparatus using induction heating of claim 10, wherein the bracket comprises:
a first part attached to the lower surface of the top plate;
a second part extending downward from the first part;
a plurality of third parts protruding inward from the second part; and
a fastening hole formed in the third part.

12. The cooking apparatus using induction heating of claim 11, wherein the third part protrudes from a corner of the second part toward the ventilation space.

13. The cooking apparatus using induction heating of claim 11, wherein the bracket further comprises a guide wall arranged on an edge of the first part.

14. The cooking apparatus using induction heating of claim 10, wherein the printed circuit board has an area, in contact with the bracket, from which a copper layer is removed.

15. A cooking apparatus using induction heating comprising:
a top plate including a heating zone on which a cooking container is placed;
a working coil located below the heating zone;
an inverter which has a plurality of switching elements, and supplies current to the working coil through an operation of the plurality of switching elements;
a first sensor which acquires vibration data in an audible frequency band; and
a controller which first determines a temperature range of contents contained in the cooking container, based on the vibration data acquired from the first sensor, secondly determines whether the temperature range, based on power amount data of the working coil, and determines the temperature range, based on a result of the first determination and a result of the second determination.

16. A cooking apparatus using induction heating comprising:
a top plate including a heating zone on which a cooking container is placed;
a working coil located below the heating zone;
an inverter which has a plurality of switching elements, and supplies current to the working coil through an operation of the plurality of switching elements;
a first sensor which acquires vibration data in an audible frequency band; and
a controller which calculates a probability for each temperature class, based on the vibration data acquired from the first sensor, and calculates a final probability for each temperature class by reflecting a transition probability corresponding to each probability for each temperature class as a weight.

17. The cooking apparatus using induction heating of claim 16, wherein the controller comprises an AI model which is trained to output the probability for each temperature class, based on frequency characteristics extracted for each temperature from the acquired vibration data.

18. The cooking apparatus using induction heating of claim 16, wherein the controller determines a temperature class having the highest probability value among the final probability for each temperature class as a current temperature.

19. The cooking apparatus using induction heating of claim 16, wherein the controller which first determines whether contents of the cooking container are boiling based on the final probability for each temperature class, secondly determines whether the contents are boiling based on power amount data of the working coil, and determines whether the contents are boiling based on a result of the first determination and a result of the second determination.
